(19) United States
(12) Patent Application Publication
(10) Pub. No.: US 2023/0180435 A1
(43) Pub. Date: Jun. 8, 2023

(54) IMMERSION-TYPE POROUS HEAT DISSIPATION STRUCTURE

(71) Applicant: AMULAIRE THERMAL TECHNOLOGY, INC., New Taipei City (TW)

(72) Inventors: CHING-MING YANG, New Taipei City (TW); CHENG-SHU PENG, New Taipei City (TW); TZE-YANG YEH, New Taipei City (TW)

(21) Appl. No.: 17/545,054

(22) Filed: Dec. 8, 2021

(51) Int. Cl. H05K 7/20; B23P 15/26

(52) U.S. Cl. CPC H05K 7/203; H05K 7/20436; B23P 15/26

(57) ABSTRACT

An immersion-type porous heat dissipation structure is provided. The immersion-type porous heat dissipation structure includes a porous heat dissipation material in a form of a sheet. A surface of the porous heat dissipation material has a plurality of open pores that are configured to generate air bubbles. A 1 mm² cross-sectional area of the surface of the porous heat dissipation has at least five of the open pores each having a depth greater than 25 μm.

### FIELD OF THE DISCLOSURE

The present disclosure relates to a heat dissipation structure, and more particularly to an immersion-type porous heat dissipation structure.

### BACKGROUND OF THE DISCLOSURE

An immersion cooling technology is to directly immerse heat producing elements (such as servers and disk arrays) into a coolant that is non-conductive, and heat generated from operation of the heat producing elements is removed through an endothermic gasification process of the coolant. Therefore, how to dissipate heat more effectively through the immersion cooling technology has long been an issue to be addressed in the industry.

### SUMMARY OF THE DISCLOSURE

In response to the above-referenced technical inadequacy, the present disclosure provides an immersion-type porous heat dissipation structure.

In one aspect, the present disclosure provides an immersion-type porous heat dissipation structure, which includes a porous heat dissipation material. The porous heat dissipation material is in a form of a sheet. At least one surface of the porous heat dissipation material has a plurality of open pores that are configured to generate air bubbles, and a 1 mm² cross-sectional area of the at least one surface of the porous heat dissipation material has at least five of the open pores each having a depth greater than 25 μm.

In certain embodiments, the depth of each of the open pores is defined by a height difference between a highest point of side walls of each of the open pores and a lowest point of each of the open pores.

In certain embodiments, a width of each of the open pores having the depth greater than 25 μm is not less than 5 μm.

In certain embodiments, the porous heat dissipation material is a porous copper heat dissipation material formed by sintering copper powder.

In certain embodiments, the immersion-type porous heat dissipation structure further includes a metal heat dissipation material. The porous heat dissipation material is arranged on the metal heat dissipation material.

In certain embodiments, the porous heat dissipation material is a porous sintered structure formed on the metal heat dissipation material by sintering copper powder.

In certain embodiments, the porous heat dissipation material is a porous spray structure formed on the metal heat dissipation material by a spray process.

In certain embodiments, the porous heat dissipation material is a porous chemically etching structure formed on the metal heat dissipation material by chemical etching.

Therefore, in the immersion-type porous heat dissipation structure provided by the present disclosure, by virtue of “the immersion-type porous heat dissipation structure having the porous heat dissipation material in the form of the sheet, the at least one surface of the porous heat dissipation material having the plurality of open pores that are configured to generate the air bubbles” and “the 1 mm² cross-sectional area of the at least one surface of the porous heat dissipation material having the at least five of the open pores each having the depth greater than 25 μm,” a heat dissipation capacity of the immersion-type porous heat dissipation structure is effectively enhanced, thereby enhancing an effect of immersion-type heat dissipation.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of an immersion-type porous heat dissipation structure according to a first embodiment of the present disclosure;

FIG. 2 is a photograph taken through a scanning electron microscope showing the immersion-type porous heat dissipation structure according to the first embodiment of the present disclosure;

FIG. 3 is a schematic view of a depth of an open pore of the immersion-type porous heat dissipation structure according to the first embodiment of the present disclosure;

FIG. 4 is a schematic view of a width of the open pore of the immersion-type porous heat dissipation structure according to the first embodiment of the present disclosure; and

FIG. 5 is a schematic view of an immersion-type porous heat dissipation structure according to a second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

[First Embodiment]

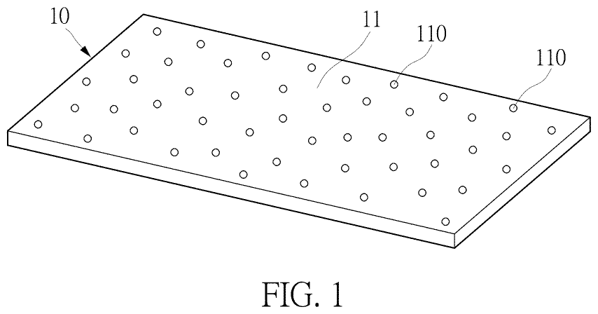

Referring to FIG. 1, in which a first embodiment of the present disclosure is shown, the first embodiment of the present disclosure provides an immersion-type porous heat dissipation structure including a porous heat dissipation material 10 that is in a form of a sheet, which can be used to contact heat generating components.

In the present embodiment, the porous heat dissipation material 10 is exemplarily an immersion-type heat sink of any size and can be immersed in an immersion cooling liquid that has a two phase property (such as electronic fluorinated liquid). In addition, at least one surface 11 of the porous heat dissipation material 10 has a plurality of open pores 110 so as to generate air bubbles, thereby enhancing a heat dissipation capacity of the porous heat dissipation material 10. It should be noted that the plurality of open pores 110 are exaggeratedly enlarged in FIG. 1 for a better understanding of the present disclosure.

Furthermore, the heat dissipation capacity of the immersion-type porous heat dissipation structure can be further improved through a cooperation of a depth of the open pore 110.

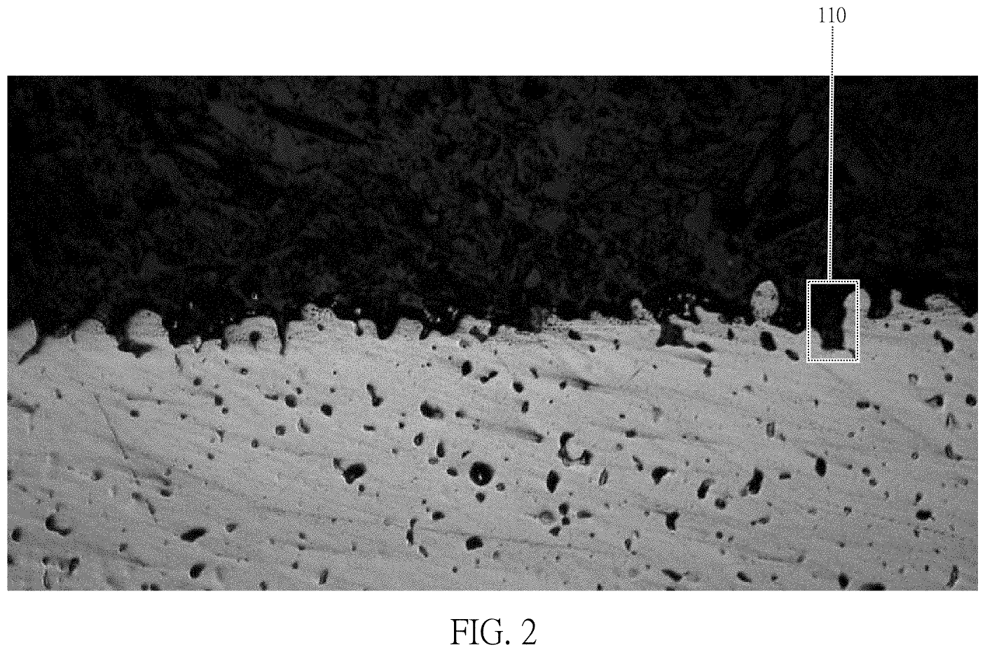

Referring to FIG. 2, which is an optical microscope image of the porous heat dissipation material 10 shown in FIG. 1, a 1 mm² cross-sectional area of the surface 11 of the porous heat dissipation material 10 is exemplified as having at least five of the open pores 110 each having the depth of greater than 25 μm.

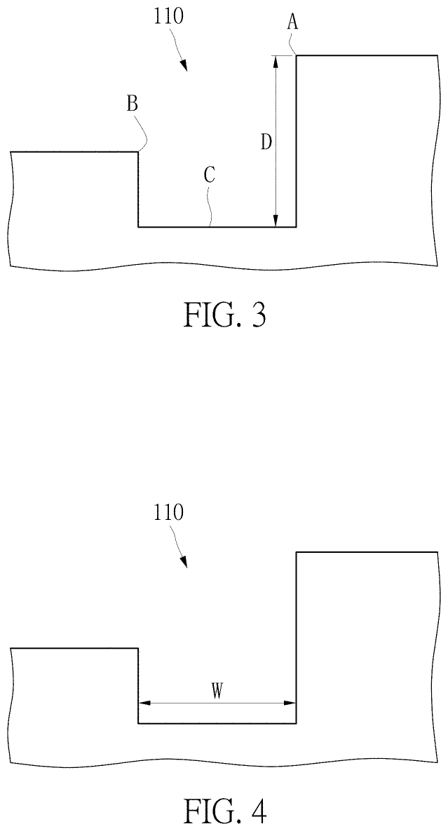

Referring to FIG. 3, in which one of the open pores 110 is exemplarily shown, two side walls of the open pore 110 respectively have a highest point A and a second highest point B, and a bottom of the open pore 110 has a lowest point C. The depth D of the open pore 110 is defined by a height difference between the highest point A of one of the two side walls of the open pore 110 and the lowest point C of the bottom of the open pore 110.

Furthermore, after actual testing, when power of a heat producing element is 200 watts to 300 watts, a thermal resistance (i.e., a ratio of a temperature change of the porous heat dissipation material to heat energy generated by the heat producing element) measured in the porous heat dissipation material 10 of the present embodiment that has 5 to 6 open pores 110 each having the depth D greater than 25 μm in the 1 mm² cross-sectional area on the surface 11, is significantly reduced in comparison to a thermal resistance of another porous heat dissipation material that has 1.2 to 3.7 open pores each having the depth D greater than 25 μm in the 1 mm² cross-sectional area of the surface, or to a thermal resistance of yet another porous heat dissipation material that has 2.5 to 4.93 open pores each having the depth D greater than 25 μm in the 1 mm² ross-sectional area of the surface, such that the heat dissipation capacity of the porous heat dissipation material 10 is effectively enhanced.

Therefore, in the present embodiment, when the 1 mm² ross-sectional area of the surface 11 of the porous heat dissipation material 10 has the at least five open pores 110 having the depth D greater than 25 m, i.e., a density of the open pores 110 having the depth D greater than 25 μm is five or more in a cross section per square millimeter (mm²) of the surface 11, or the density of the open pores 110 having the depth greater than 25 μm is 5/mm² or more, the heat dissipation capacity of the immersion-type porous heat dissipation structure can be effectively enhanced.

Furthermore, the heat dissipation capacity of the immersion-type porous heat dissipation structure can be further improved through a cooperation of the depth of the open pore 110 and a width of the open pore 110.

Referring to FIG. 4, in which another one of the open pores 110 is exemplarily shown, the width W of the open pore 110 is defined by a distance between the two side walls of the open pore 110. Moreover, the width W of each of the open pores 110 having the depth D greater than 25 μm cannot be less than 5 μm, so that the heat dissipation capacity of the immersion-type porous heat dissipation structure can be effectively enhanced.

In addition, the porous heat dissipation material 10 of the present embodiment can be a porous copper heat dissipation material that is made of copper. Moreover, the porous heat dissipation material 10 of the present embodiment can be the porous copper heat dissipation material formed by sintering copper powder.

[Second Embodiment]

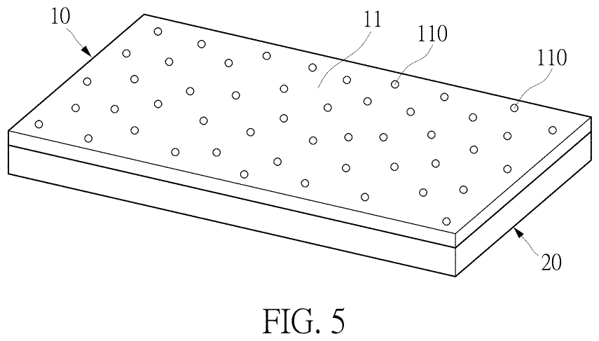

Referring to FIG. 5, in which a second embodiment of the present disclosure is shown, an immersion-type porous heat dissipation structure of the second embodiment is substantially the same as that of the first embodiment, and differences therebetween are described as follows.

In the present embodiment, the immersion-type porous heat dissipation structure further includes a metal heat dissipation material 20, and the porous heat dissipation material 10 is arranged on the metal heat dissipation material

Furthermore, the porous heat dissipation material 10 of the present embodiment can be a porous sintered structure formed on the metal heat dissipation material 20 by sintering copper powder. In addition, the porous heat dissipation material 10 of the present embodiment can be a porous spray structure formed on the metal heat dissipation material 20 by a spray process. Moreover, the porous heat dissipation material 10 of the present embodiment can be a porous chemically etched structure formed on the metal heat dissipation material 20 by chemical etching. Therefore, the immersion-type porous heat dissipation structure of the present embodiment has the porous heat dissipation material 10 formed on the metal heat dissipation material 20, so that an overall heat dissipation effect can be further enhanced.

[Beneficial Effects of the Embodiments]

In conclusion, in the immersion-type porous heat dissipation structure provided by the embodiments of the present disclosure, by virtue of “the immersion-type porous heat dissipation structure having the porous heat dissipation material in the form of the sheet, the at least one surface of the porous heat dissipation material having the plurality of open pores that are configured to generate the air bubbles” and “the 1 mm² cross-sectional area of the at least one surface of the porous heat dissipation material having the at least five of the open pores each having the depth greater than 25 μm,” the heat dissipation capacity of the immersion-type porous heat dissipation structure is effectively enhanced, thereby enhancing an effect of immersion-type heat dissipation.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An immersion-type porous heat dissipation structure, comprising:
a porous heat dissipation material in a form of a sheet;
wherein at least one surface of the porous heat dissipation material has a plurality of open pores that are configured to generate air bubbles, and a 1 mm² cross-sectional area of the at least one surface of the porous heat dissipation material has at least five of the open pores each having a depth greater than 25 μm.

2. The immersion-type porous heat dissipation structure according to claim 1, wherein the depth of each of the open pores is defined by a height difference between a highest point of side walls of each of the open pores and a lowest point of each of the open pores.

3. The immersion-type porous heat dissipation structure according to claim 1, wherein a width of each of the open pores having the depth greater than 25 μm is not less than 5 μm.

4. The immersion-type porous heat dissipation structure according to claim 1, wherein the porous heat dissipation material is a porous copper heat dissipation material formed by sintering copper powder.

5. The immersion-type porous heat dissipation structure according to claim 1, further comprising:
a metal heat dissipation material;
wherein the porous heat dissipation material is arranged on the metal heat dissipation material.

6. The immersion-type porous heat dissipation structure according to claim 5, wherein the porous heat dissipation material is a porous sintered structure formed on the metal heat dissipation material by sintering copper powder.

7. The immersion-type porous heat dissipation structure according to claim 5, wherein the porous heat dissipation material is a porous spray structure formed on the metal heat dissipation material by a spray process.

8. The immersion-type porous heat dissipation structure according to claim 5, wherein the porous heat dissipation material is a porous chemically etching structure formed on the metal heat dissipation material by chemical etching.
